(19) United States
(12) Patent Application Publication
(10) Pub. No.: US 2004/0108137 A1
(43) Pub. Date: Jun. 10, 2004

(54) CROSS CONNECT VIA FOR MULTILAYER PRINTED CIRCUIT BOARDS

(75) Inventors: Stephen J. VETTER, Strafford, MO (US); Thomas D. MURRY, Springfield, MO (US); Randolph A. LATALL, Springfield, MO (US); Sharon L. COOK, Springfield, MO (US); Eric W. MONTGOMERY, Springfield, MO (US)

Correspondence Address: MARSTELLER & ASSOCIATES, P.C., PO BOX 803302, DALLAS, TX, 75380-3302, US

(73) Assignee: LITTON SYSTEMS, INC., Los Angeles, CA (US)

(21) Appl. No.: 10/604,429

(22) Filed: Jul. 21, 2003

Related U.S. Application Data
(60) Provisional application No. 60/319,764, filed on Dec. 10, 2002.

(51) Int. Cl. H01R 12/06; H05K 1/14

(52) U.S. Cl. 174/262; 174/266; 174/264; 174/267

(57) ABSTRACT

A printed circuit board (B) with a mechanical attachment of connector pins (42a and 42b) to opposite sides of the same plated through location (34) maintains electrical isolation between the board sides (14 and 16). A sequence of controlled depth drilling steps creates a hole (34) through the printed circuit board (B) with multiple diameters (20, 24, 30 and 40).

### CROSS REFERENCE TO RELATED APPLICATIONS

This application claims the benefit of U.S. Provisional Application Ser. No. 60/319,764, filed Dec. 10, 2002, entitled CROSS CONNECT VIA FOR MULTILAYER PRINTED CIRCUIT BOARDS.

### BACKGROUND OF INVENTION

1. Technical Field.

The invention relates to the field of printed circuit boards and more particularly to a processing method for achieving a mechanical attachment to both sides of a printed circuit board a single plated through hole without electrical conductivity.

2. Background Art.

The present invention is a printed circuit board processing technique that allows mechanical attachment of press fit pins to opposite sides of the same plated through location while maintaining electrical isolation between them. This invention is realized through a sequence of controlled depth drilling steps that creates a hole through the printed circuit board with multiple diameters.

A problem arises when networking topologies, such as cross point switches, are implemented in mid-plane applications. Mid-plane configurations are connectorized from both sides of the printed circuit board. Normally, connectors must be offset from side to side to eliminate mechanical interference so that the pins may be electrically isolated. New high density connector designs are not suitable in these applications because the pin density is too high to allow for a mechanical offset. The present invention eliminates the need to mechanically offset the connectors thus allowing the use of high density connector designs in these applications.

Mid-plane back-panels are a special back-panel design where there are daughter cards attached to both sides of the back-panel. Mid-planes are typical in large cross point switch designs found in telecommunications and data storage industries.

A prior method, which could be used to solve this problem, is known in the industry as sequential lamination. Sequential lamination is a process where a partial group of layers is processed through the normal multi-layer lamination process, drilled and plated and then combined with other parts in a subsequent lamination operation to yield the completed assembly.

However, sequential lamination adds significant cost to the end product through multiple repetitions of drilling, plating, imaging, and lamination processes. These repetitive processes add significant cost to the manufacturing process.

While the above cited references introduce and disclose a number of noteworthy advances and technological improvements within the art, none completely fulfills the specific objectives achieved by this invention.

### SUMMARY OF INVENTION

In accordance with the present invention, a printed circuit board adapted to mount electrical circuitry has at least one base layer and first and second opposing surfaces. A first through passageway having a first passageway diameter extends through the base layer from the first surface to the second surface. A first bore hole having a first bore diameter and concentric with the first through passageway is formed between the first surface and a desired first depth in the base layer between the first and second surfaces. The first bore diameter is preferably greater than the first passageway diameter.

A second bore hole having a second bore diameter and concentric with the first through passageway is formed or drilled between the second surface and a desired second depth in the base layer between the first and second surfaces. The second bore diameter is greater than the first passageway diameter.

The first through passageway, first bore hole, and second bore hole form a desired open structure. The open structure is then plated with a desired conductive material, such as copper, silver, or gold.

A second through passageway concentric with the first through passageway extending through the open structure is then formed in the base layer, and opens the passageway from the first surface to the second surface. The second through passageway having a second passageway diameter at least as large as the first passageway diameter to electrically isolate the first surface from the second surface.

A known first connector pin compatible with at least a first portion of the open structure is then inserted into the open structure from the first surface. Similarly, a second connector pin compatible with at least a second portion of the open structure is then inserted into the open structure from the second surface.

These and other objects, advantages and features of this invention will be apparent from the following description taken with reference to the accompanying drawings, wherein is shown the preferred embodiments of the invention.

### BRIEF DESCRIPTION OF DRAWINGS

A more particular description of the invention briefly summarized above is available from the exemplary embodiments illustrated in the drawings and discussed in further detail below. Through this reference, it can be seen how the above cited features, as well as others that will become apparent, are obtained and can be understood in detail. The drawings nevertheless illustrate only typical, preferred embodiments of the invention and are not to be considered limiting of its scope as the invention may admit to other equally effective embodiments.

FIGS. 1A through 1F depict a series of cross sections showing boring and plating operations through a known printed circuit board.

FIG. 2 depicts a cross section of a known connector pin being inserted into the circuit board through a prepared via in accordance with the present invention.

FIG. 3 is a series of vias prepared in accordance with the present invention in a variety of printed circuit cross-sections.

### DETAILED DESCRIPTION

So that the manner in which the above recited features, advantages, and objects of the present invention are attained can be understood in detail, more particular description of the invention, briefly summarized above, may be had by reference to the embodiment thereof that is illustrated in the appended drawings. In all the drawings, identical numbers represent the same elements.

A printed circuit board B adapted to mount electrical circuitry 10 has at least one base layer 12 and a first and second opposing surfaces 14 and 16 respectively. A first bore hole 22 having a first bore diameter 24 extends into the base layer 12 to a predetermined first depth 26 from the first surface 14 and between the first surface 14 and the second surface 16. A first through bore hole or passageway 18 having a first passageway diameter 20 and concentric with the first bore hole 22 is formed extending from the first surface to a predetermined depth 50 from the first surface 14 less than the total thickness 52 of the circuit board B; or, alternatively, the first through passageway 18 may be formed generally extending through the base layer 12 from the first surface 14 to the second surface 16.

The first bore diameter 24 is preferably greater than the first through passageway diameter 20, or in other words, the first through passageway diameter 20 is smaller that the first bore diameter 24.

A second bore hole 28 having a second bore diameter 30 and concentric with the first through passageway 18 is formed or drilled between the second surface 16 and a desired second depth 32 in the base layer 12 between the first and second surfaces 14 and 16. The second bore diameter 30 is greater than the first passageway diameter 20.

The depth 50 of the first through hole 18 plus the depth 32 of the second bore hole 28 must equal or exceed the total thickness 52 of the printed circuit board B.

The first through passageway 18, first bore hole 22, and second bore hole 28 comprising a desired open structure 34. The open structure 34 is then plated with a desired conductive material 36, such as copper, silver, or gold.

A second through passageway 38 concentric with the first through passageway 18 extending through the open structure 34 is then formed in the base layer 12 and inures the opening of a passageway from the first surface to the second surface 14 and 16 respectively. The second through passageway 38 having a second passageway diameter 40 at least as large as the first passageway diameter 24 to electrically isolate the first surface 14 from the second surface 16. The through hole structure 54 thus formed may be electroplated to a specified finished hole diameter to receive the specified compliant connector pin 42.

A known first connector pin 42a compatible with at least a first portion 44 of the open structure 34 is then inserted into the open structure 34 from the direction of the first surface 14. Similarly, a second connector pin 42b compatible with at least a second portion 46 of the open structure 34 is then optionally inserted into the open structure 34 from the direction of the second surface 16. The size and depth penetration of the connector pins 42a and 42b are chosen as desired.

The connector pins 42a and 42b generally are known press fit type pins to allow simple mechanical attachment to the printed circuit board B.

Since the holes formed in the printed circuit board B are normally done with a drill or a laser beam, generally the holes are cylindrical voids 32 formed in the base layer 12 of the circuit board B.

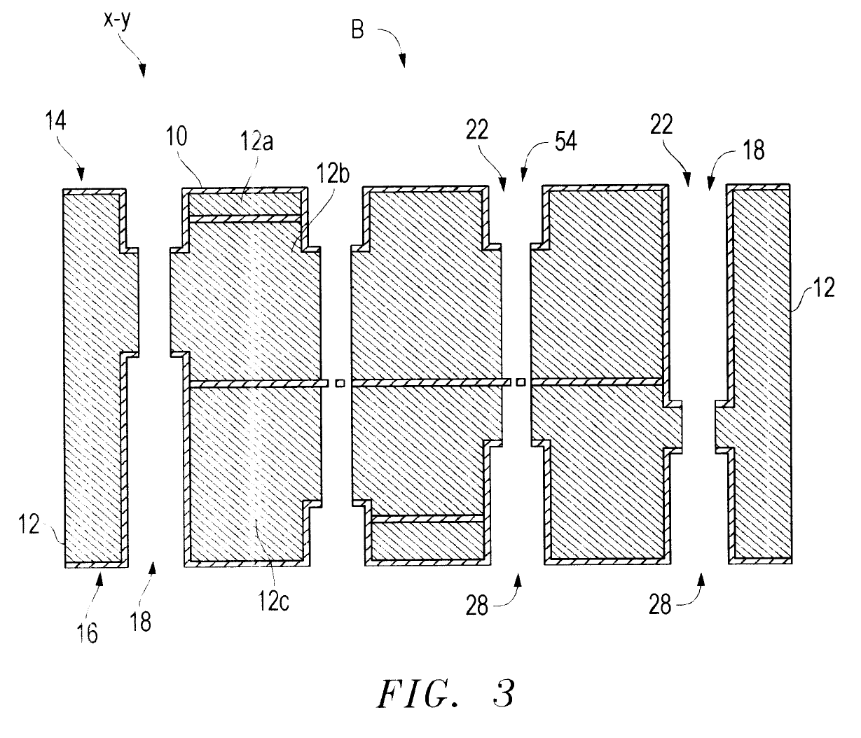

Referring particularly to FIG. 3, the benefit of the present invention allowing the same x-y location to be electrically isolated from top to bottom of the printed circuit board B. FIG. 3 also illustrates the flexibility of the present invention through varying depths of drill operations allowing hole at one x-y location to be connected to another x-y location on the opposite side of the printed circuit board B and also with circuit boards having multiple layers 12a, 12b, and 12c for example and different interior characteristics.

In the most basic embodiment of the present invention, a hole is partially drilled to a predetermined depth at the required diameter from both sides at the same x-y location. A smaller diameter hole is drilled through the remaining material to allow subsequent chemistry to flow completely through for plating purposes. The small center hole is drilled out in a final step to remove the electrical connection between the two sides.

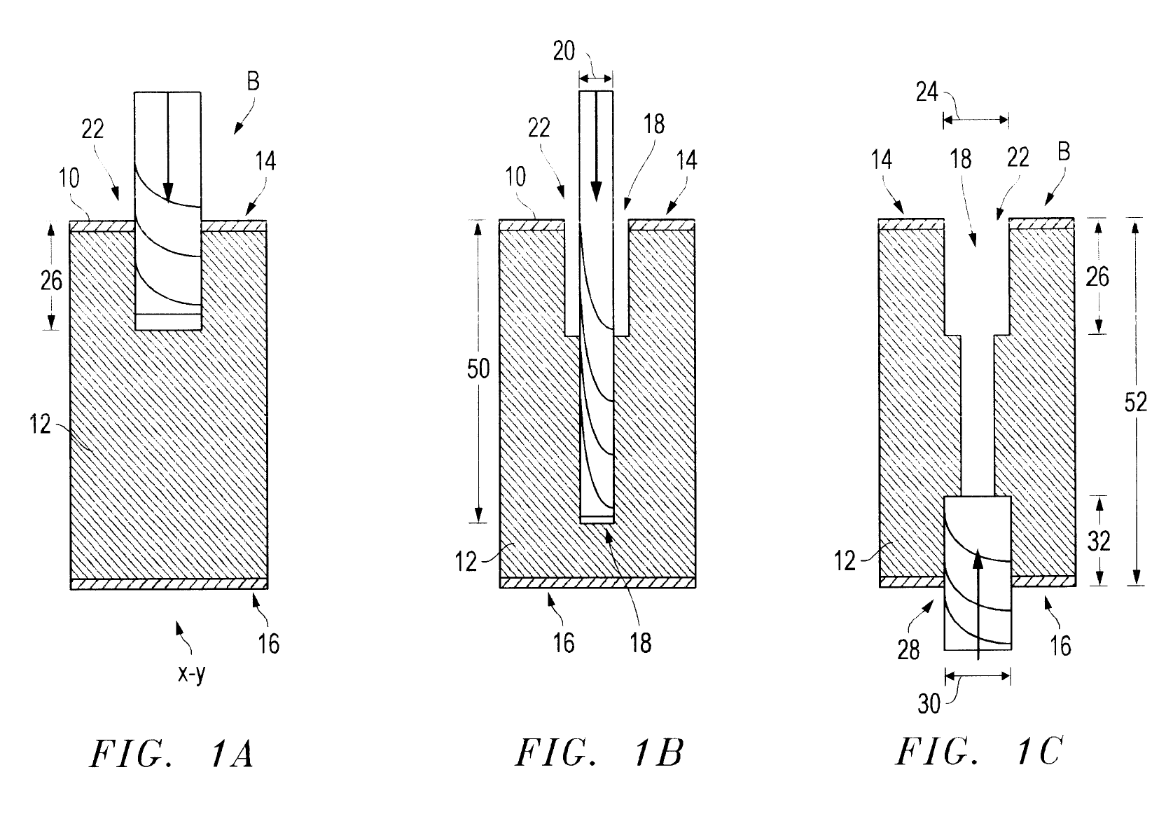

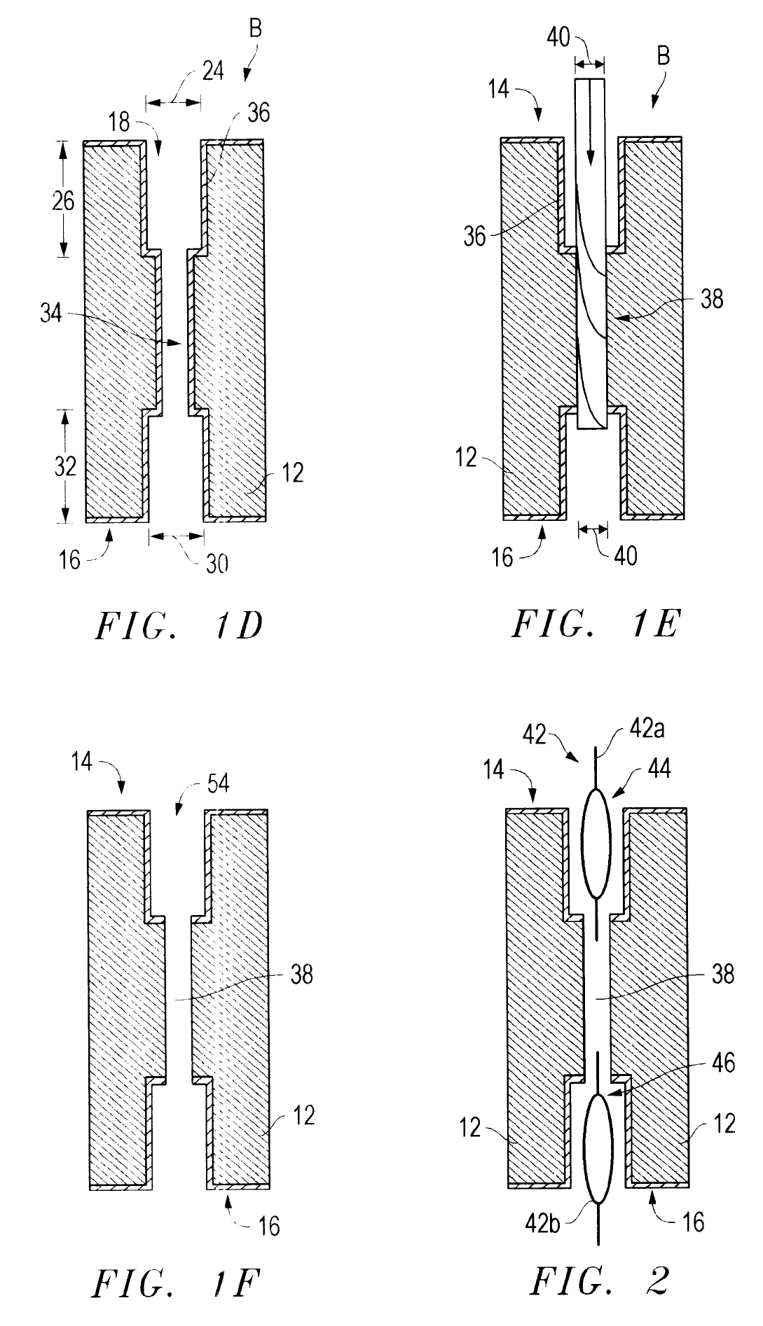

Specifically referring to FIGS. 1A through 1F and FIG. 2, the following steps may be followed:

1. In a first drill operation, the first bore hole 22 is formed to a desired depth 26 in the printed circuit board B.

2. In a second drill operation the first through passageway 18 is drilled to a predetermined depth 50 from the first surface 14 at the same x-y location as the first drill operation. Diameter 24 is greater than diameter 20.

3. In a third drill operation a second bore hole 28 is created to a predetermined depth 32 from the second surface 16 to create a complete opening 34 through the printed circuit board B.

4. A thin layer or application of an electroless metal, such as copper, may be deposited onto the walls of the drilled or open structure 34 with a known electroless process. Then a thing electroplated copper layer may be plated to provide mechanical integrity to the structure during subsequent processing. Alternatively, another chosen conductor such as copper, silver, gold or the like, may be deposited.

5. A fourth drill operation drills a second through passageway 38 through the depth of the first operation to desirably remove the copper or other metallic plating. Diameter 40 is preferably slightly larger than diameter 20 to electrically isolate the first surface 14 from the second surface 16.

6. The final structure 54 may be electroplated to a specified finished hole diameter to receive the specified compliant connector pin 42.

7. Compliant press-fit connector pins 42a and 42b are inserted from both sides of the printed circuit board B at the same x-y location.

While the term copper may have been used to describe the present invention, any suitable conductive method or compound may be used as chosen for the specific application.

Alternatively, a first through passageway 18 having a first passageway diameter 20 is formed first and extends through the base layer 12 from the first surface 14 to the second surface 16. A first bore hole 22 having a first bore diameter 24 and concentric with the first through passageway 18 is then formed between the first surface 14 and a desired first depth 26 in the base layer 12 between the first and second surfaces 14 and 16. The first bore diameter 24 is preferably greater than the first passageway diameter 20.

A second bore hole 28 having a second bore diameter 30 and concentric with the first through passageway 18 is then formed or drilled between the second surface 16 and a desired second depth 32 in the base layer 12 between the first and second surfaces 14 and 16. The second bore diameter 30 is greater than the first passageway diameter 20.

The remaining steps in this alternative embodiment remains the same as above disclosed.

The foregoing disclosure and description of the invention are illustrative and explanatory thereof, and various changes in the size, shape and materials, as well as in the details of the illustrated construction may be made without departing from the spirit of the invention.

1. A printed circuit board adapted to mount electrical circuitry of the type having at least one base layer formed with first and second opposing surfaces, the invention comprising:
a first through passageway having a first passageway diameter extending through the base layer from the first surface to a desired depth from the first surface between the first and second surfaces;
a first bore hole having a first bore diameter and concentric with the first through passageway formed between the first surface and a desired first depth in the base layer between the first and second surfaces; the first bore diameter being smaller than the first passageway diameter;
a second bore hole having a second bore diameter and concentric with the first through passageway formed between the second surface and a desired second depth in the base layer between the first and second surfaces; the second bore diameter being greater than the first passageway diameter;
the first through passageway, first bore hole, and second bore hole comprising a desired open structure communicating between the first surface and the opposing second surface;
the open structure being plated with a desired conductive material; and,
a second through passageway concentric with the first through passageway extending through the open structure formed in the base layer from the first surface to the second surface; the second through passageway having a second passageway diameter at least as large as the first passageway diameter; the second through passageway being formed subsequent to plating of the open structure.

2. The invention of claim 1 further including a first connector pin compatible with at least a first portion of the open structure being inserted into the open structure from the first surface; and, a second connector pin compatible with at least a second portion of the open structure being inserted into the open structure from the second surface.

3. The invention of claim 1 wherein the printed circuit board includes multiple layers.

4. The invention of claim 1 wherein the holes formed in the printed circuit board form cylindrical voids.

5. The invention of claim 1 wherein a layer of electroless metal is deposited onto walls of the open structure; and, a further comparable metallic layer is electroplated over the electroless metal deposition.

6. The invention of claim 5 wherein the metal is copper.

7. A method for adapting a printed circuit board of the type adapted to mount electrical circuitry of the type having at least one base layer formed with first and second opposing surfaces to provide a mechanical attachment to both sides a single through hole without electrical continuity, the invention comprising:
forming a first through passageway having a first passageway diameter extending through the base layer from the first surface to the second surface;
forming a first bore hole having a first bore diameter and concentric with the first through passageway and between the first surface and a desired first depth in the base layer between the first and second surfaces; the first bore diameter being greater than the first passageway diameter;
forming a second bore hole having a second bore diameter concentric with the first through passageway between the second surface and a desired second depth in the base layer between the first and second surfaces; the second bore diameter being greater than the first passageway diameter;
the first through passageway, first bore hole, and second bore hole comprising a desired open structure communicating between the first surface and the opposing second surface;
plating the open structure with a desired conductive material; and,
forming a second through passageway concentric with the first through passageway extending through the open structure in the base layer from the first surface to the second surface; the second through passageway having a second passageway diameter at least as large as the first passageway diameter; the second through passageway being formed after the open structure is electroplated.

8. The method of claim 7 further including the step of inserting a first connector pin compatible with at least a first portion of the open structure into the open structure from the first surface; inserting a second connector pin compatible with at least a second portion of the open structure into the open structure from the second surface.

9. The method of claim 7 wherein the printed circuit board includes multiple layers.

10. The method of claim 7 wherein the holes formed in the printed circuit board form cylindrical voids.

11. The method of claim 7 wherein a layer of electroless metal is deposited onto walls of the open structure; and, a further comparable metallic layer is electroplated over the electroless metal deposition.

12. The method of claim 11 wherein the metal is copper.

13. A method for adapting a printed circuit board of the type adapted to mount electrical circuitry of the type having at least one base layer formed with first and second opposing surfaces to provide a mechanical attachment to both sides a single through hole without electrical continuity, the invention comprising:
forming a first bore hole having a first bore diameter between the first surface and a desired first depth in the base layer between the first and second surfaces;
forming a first through passageway having a first passageway diameter extending through the base layer from the first surface to the second surface; the first through passageway being formed concentric with the first bore hole; the first bore diameter being greater than the first through passageway diameter;
forming a second bore hole having a second bore diameter concentric with the first through passageway between the second surface and a desired second depth in the base layer between the first and second surfaces; the second bore diameter being greater than the first passageway diameter;
the first through passageway, first bore hole, and second bore hole comprising a desired open structure communicating between the first surface and the opposing second surface;
plating the open structure with a desired conductive material; and,
forming a second through passageway concentric with the first through passageway extending through the open structure in the base layer from the first surface to the second surface; the second through passageway having a second passageway diameter at least as large as the first passageway diameter; the second through passageway being formed after the open structure is electroplated.

14. The method of claim 13 further including the step of inserting a first connector pin compatible with at least a first portion of the open structure into the open structure from the first surface; inserting a second connector pin compatible with at least a second portion of the open structure into the open structure from the second surface.

15. The method of claim 13 wherein the printed circuit board includes multiple layers.

16. The method of claim 13 wherein the holes formed in the printed circuit board form cylindrical voids.

17. The method of claim 13 wherein a layer of electroless metal is deposited onto walls of the open structure; and, a further comparable metallic layer is electroplated over the electroless metal deposition.

18. The method of claim 17 wherein the metal is copper.
